(19) United States
(12) Patent Application Publication
(10) Pub. No.: US 2011/0183067 A1
(43) Pub. Date: Jul. 28, 2011

(54) CARBON NANO TUBE COATING APPARATUS AND METHOD THEREOF

(75) Inventors: Jhinsup Jhung, Seoul (KR); Young Soo Son, Yongin-si (KR); Byoungmin Kim, Goyang-si (KR)

(73) Assignee: NANOBASE INC., Seoul (KR)

(21) Appl. No.: 12/679,076

(22) PCT Filed: Sep. 22, 2008
(86) PCT No.: PCT/KR2008/005633

§ 371 Date: Mar. 19, 2010

(30) Foreign Application Priority Data
Sep. 21, 2007 (KR) 10-2007-0096299

(51) Int. Cl. B05D 5/12; B05C 11/00; C23C 16/00

(52) U.S. Cl. 427/122; 118/46; 118/718

(57) ABSTRACT

The present invention relates to an apparatus and method for coating carbon nano tubes, which is capable of coating carbon nano tubes on a film at the same time when the carbon nano tubes are produced, unlike a wet method, thereby reducing the number of processes and costs and improving performance. The apparatus and method has an advantage of directly applying a CNT-containing gas obtained by thermal chemical vapor deposition to a film to obtain a CNT coating film with the reduced numbers of processes and high quality through improvement of an electrical property by maintenance of dispersibility and CNT length, as compared to a conventional wet process.

### TECHNICAL FIELD

The present invention relates to an apparatus and method for coating carbon nano tubes, and more particularly, to an apparatus and method for coating carbon nano tubes, which is capable of coating carbon nano tubes on a film at the same time when the carbon nano tubes are produced, unlike a wet method, thereby reducing the number of processes and costs and improving performance.

### BACKGROUND ART

A carbon nano tubes (CNT) are allotropes of carbon with a cylindrical structure which has its diameter of 1 to 20 nm. This cylindrical structure has a unique bond arrangement of a robust and flat hexagonal plate-like film structure rolled into a spiral form to form CNT, whose edges are combined together at different points. Upper and lower portions of the hexagonal plate-like film structure are filled with free electrons which move in parallel to the structure in a discrete state.

An electrical characteristic of CNT may be divided into an insulator, a semiconductor and metal based on its structure and diameter difference. For example, when chirality of CNT is changed, movement of free electrons is accordingly changed. With such change of movement, CNT may take either conductive property such as metal due to completely free movement of free electrons or semiconductor property due to existence of a potential barrier which is to be overcome. In this case, the size of the barrier depends on the diameter of CNT and it is known that 1 eV of the barrier is possible at the minimum diameter of CNT. In other words, CNT has electrical conductivity similar to that of copper, the same thermal conductivity as diamond which has the highest thermal conductivity in the natural world, and strength which is 100,000 times as high as steel. In addition, whereas a carbon fiber is cut at even 1% of deformation, CNT stands against up to 15% of deformation and has various excellent properties including tensile force higher than that of diamond.

As described above, since CNT has excellent mechanical robustness and chemical stability as well as both of semiconductor and conductor properties, and is small in its diameter, long in its length and is hollowed, CNT has excellent properties as materials for flat display devices, transistors, energy storages, etc., and has very high applicability to various kinds of nano-sized electronic devices.

With such a range of diverse utilization of CNT, when CNT utilizes its transparency due to its fineness to an electrode pattern or an electrode plane, it becomes possible to apply electrodes of various uses for diverse objects. In order to maximize such utilization, there has appeared a CNT coating film, i.e., a film coated with CNT, by use of which it becomes possible to implement electromagnetic shielding or anti-static adhesive sheets, electrodes or light emitting parts of a display, transparent electrodes of electronic paper, transparent heaters, etc.

FIG. 1 shows a simplified process flow diagram of a general method of manufacturing a CNT coating film. As shown, this method generally includes Step S1 of preparing a CNT raw material, Step S2 of pulverizing or cutting the prepared CNT raw material, Step S3 of making CNT dispersion by dispersing the pulverized or cut CNT into a solution such as organic solvent/water/surfactant, and Step S4 of coating the CNT dispersion on an object film. In some cases, the CNT raw material may be pulverized or cut without requiring the pulverizing or cutting step separately. However, the pulverizing or cutting step is preferably performed for even dispersion.

In more detail, in the general CNT coating film manufacturing method, soot-like CNT is obtained through a separate CNT making process, CNT powder is obtained through a separate process of pulverizing or cutting the CNT to be evenly dispersed, and a CNT dispersion is obtained through a separate process of dispersing the CNT powder into a solution according to coating purpose. Thereafter, the obtained CNT dispersion is coated on a film or substrate by means of spraying, printing, dipping or the like. Like this, the above-described general CNT coating film manufacturing method requires many processes.

FIG. 2 illustrates the general CNT coating film manufacturing method in a visual manner when a CNT coating film is manufactured in successive processes. As shown, CNT dispersion 40 is obtained by pulverizing or cutting soot-like CNT 30 obtained by thermal chemical vapor deposition to cause a raw material and a catalyst 10 to react with a gas 11 in a high-temperature reactor 20 and dispersing the pulverized or cut CNT into a solution, and a CNT coating product 60 is obtained by coating the obtained CNT dispersion on a coating object by spraying or printing by means of a coating means 50, and fixing the coated CNT dispersion by firing or drying. Accordingly, such a general CNT coating film manufacturing method requires a number of equipments and complicated processes and has increased costs and low yield due to various management factors occurring in the course of processes. In addition, this method requires high costs to secure a work space for each process, which results in increase of prices of CNT coating films.

Furthermore, the existing wet method requires material such as a solution for making a CNT dispersion and means such as a mechanical article for storing the material appropriately and lowers conductivity of CNT due to CNT pulverization or cut for dispersion.

In addition, when the CNT dispersion is coated, a dispersing agent remaining in the dispersion after drying or firing process lowers conductivity of CNT, which results in deterioration of performance of the CNT coating film. Moreover, it is difficult to evenly disperse CNT in the CNT dispersion and coat CNT in such an even dispersion condition, which results in great variation in CNT density of the CNT coating film.

### DISCLOSURE

### Technical Problem

To overcome the above problems of the wet CNT coating film manufacturing method, it is an object of the present invention to provide an apparatus and method for coating a carbon nano tube, which is capable of directly applying a CNT-containing gas obtained by thermal chemical vapor deposition to a film to obtain a CNT coating film with the reduced numbers of processes and higher quality.

It is another object of the present invention to provide an apparatus and method for coating a carbon nano tube, which is capable of manufacturing a CNT coating film through only a dry process, thereby significantly reducing a required process space and lowering process costs as compared to a wet process.

It is still another object of the present invention to provide an apparatus and method for coating a carbon nano tube, which is capable of applying a variety of forms of rollers and reactor extensions depending on the shape of roller part and the kind of desired product by combining the roller part for deposition coating and film conveying with a reactor performing thermal chemical vapor deposition, thereby decreasing costs for change of process facility for product modification and providing free facility configuration.

It is yet still another object of the present invention to provide an apparatus and method for coating a carbon nano tube, which is capable of directly depositing CNT on a roller for conveying a film by forming the roller at an end portion of a reactor which generates CNT, and forming a pattern in the roller and mass-producing a CNT coating film having a certain pattern in the shortest process.

It is yet still another object of the present invention to provide an apparatus and method for coating a carbon nano tube, which is capable of improving dispersibility or electrical property of CNT by directly depositing CNT on a film using a film supplying roller combined to a CNT generating reactor without generating CNT separately, and separately collecting CNT in a region not coated on the film.

It is yet still another object of the present invention to provide an apparatus and method for coating a carbon nano tube, which is capable of coating CNT on a variety of coating objects by forming a coating means for lowering the temperature of coating objects in a CNT generating reactor and by coating CNT on the coating objects located on the coating means depending on the shape of the coating objects.

### Technical Solution

To achieve the above objects, according to an aspect, the present invention provides a carbon nano tube coating apparatus comprising: a reactor which remains at a predetermined range of high temperature for generating a carbon nano tube-containing gas; and a coating and film supplying unit including a roller which is formed in an end portion of the reactor, remains at a temperature lower than the temperature of the reactor, and is deposited with a carbon nano tube from a high temperature carbon nano tube-containing gas which is generated in the reactor and has the temperature range of the reactor; and a means for conveying a film through the roller.

Preferably, the coating and film supplying unit is disposed in a space formed by extending the end portion of the reactor in an airtight manner.

Preferably, the coating and film supplying unit is configured to convey the film to the roller so that the carbon nano tube is directly deposited on the film or is configured to transfer and coat the carbon nano tube deposited on the roller on the film using a separate compressing roller.

Preferably, the roller has an embossed pattern to be coated on the film.

Preferably, the roller includes a means for recovering a carbon nano tube deposited on a portion of the roller where the roller does not contact the film.

Preferably, the roller includes an axis through which a liquid refrigerant passes.

Preferably, the carbon nano tube coating apparatus further includes a means for washing the coated film obtained through the coating and film supplying unit or coating the coated film obtained through the coating and film supplying unit with a polymer.

According to another aspect, the present invention provides a carbon nano tube coating apparatus comprising: a carbon nano tube generating unit for generating a carbon nano tube-containing gas in a reactor having a predetermined range of temperature based on a transporting gas, a raw material, a catalyst and an auxiliary material; a roller unit including a cooling means disposed in an end portion of the reactor for directly depositing a carbon nano tube from the carbon nano tube-containing gas remaining at the temperature of the reactor; a film supplying unit for supplying a film to the roller unit and winding the film passing through the roller unit; and a reactor extension extended from the reactor such that at least the roller unit is exposed to the inner side of the reactor, a gas discharging port being formed in a portion of the reactor extension.

According to still another aspect, the present invention provides a carbon nano tube coating method comprising the steps of: providing a transporting gas, a raw material, a catalyst and an auxiliary material to a reactor and generating a carbon nano tube-containing gas in a thermal chemical vapor deposition manner; and while the generated carbon nano tube-containing gas of the temperature of the reactor passes a roller, which is located in an end portion of the reactor and has a temperature lower than the temperature of the reactor, through the reactor, directly coating a carbon nano tube contained in the carbon nano tube-containing gas on a film passing through the roller.

Preferably, the coating step comprises the step of depositing the carbon nano tube contained in the carbon nano tube-containing gas on the roller and compressively coating the carbon nano tube deposited on the roller on the film passing between the roller and an auxiliary roller disposed adjacent to the roller.

Preferably, the coating step comprises the step of depositing the carbon nano tube contained in the carbon nano tube-containing gas on a surface of the film passing through the roller.

Preferably, the coating step includes the step of recovering a carbon nano tube deposited on a non-coated region of the roller through a recovery means.

Preferably, the coating step includes the step of depositing the carbon nano tube in the carbon nano tube-containing gas according to a pattern formed on the roller and compressively coating the deposited carbon nano tube on the film passing between the roller and an auxiliary roller disposed adjacent to the roller according to the pattern formed on the roller.

Preferably, the carbon nano tube coating method further comprises, after the coating step, a post-processing step of washing the coated film or coating and fixing the coated film with a polymer.

According to yet still another aspect, the present invention provided a carbon nano tube coating apparatus comprising: a reactor for thermal chemical vapor deposition of a carbon nano tube; a reactor extension extending from an end portion of the reactor for forming a coating space to which a carbon nano tube-containing gas generated in the reactor is supplied; and a coating means located within the reactor extension for keeping an object to be coated with the carbon nano tube contained in the carbon nano tube-containing gas at a temperature lower than the temperature of the reactor and the temperature of the carbon nano tube-containing gas.

Preferably, the coating means comprises a position varying means for varying a position of the object to be coated such that a coating region of the coating object is evenly exposed to the carbon nano tube-containing gas provided through the reactor while lowering the temperature of the coating object.

Preferably, the coating means comprises a cooling means for lowering the temperature of the object to be coated and a supplying means for consecutively supplying the object to be coated to the cooling means.

Preferably, the object to be coated is at least one of an intermittent object including a plate-like slice and a cubic object with unevenness and a consecutive object including a film and a plate-like object which can be consecutively supplied.

### Advantageous Effects

The apparatus and method for coating a carbon nano tube according to an embodiment of the present invention has an advantage of directly applying a CNT-containing gas obtained by thermal chemical vapor deposition to a film to obtain a CNT coating film with the reduced numbers of processes and high quality through improvement of an electrical property by maintenance of dispersibility and CNT length, as compared to a conventional wet process.

The apparatus and method for coating a carbon nano tube according to another embodiment of the present invention has an advantage of manufacturing a CNT coating film through only a dry process, thereby significantly reducing a required process space and lowering process costs and hence increasing product competitiveness, as compared to a wet process requiring a plurality of separate processes.

The apparatus and method for coating a carbon nano tube according to still another embodiment of the present invention has an advantage of applying a variety of forms of rollers and reactor extensions depending on the shape of roller part and the kind of desired product by combining the roller part for deposition coating and film conveying with a reactor performing thermal chemical vapor deposition, thereby decreasing costs for change of process facility for product modification and providing free facility configuration.

The apparatus and method for coating a carbon nano tube according to yet still another embodiment of the present invention has an advantage of forming a pattern on a roller on which CNT is deposited and mass-producing a CNT coating film having a certain pattern in the shortest process.

The apparatus and method for coating a carbon nano tube according to yet still another embodiment of the present invention has an advantage of improving dispersibility or electrical property of CNT by directly depositing CNT on a film using a film supplying roller combined to a CNT generating reactor without generating CNT separately, and separately collecting CNT in a region not coated on the film for manufacturing a plurality of CNT products in a single process or at least obtaining an incidental CNT separately.

The apparatus and method for coating a carbon nano tube according to yet still another embodiment of the present invention has an advantage of coating CNT on a variety of coating objects by forming a coating means for lowering the temperature of coating objects in a CNT generating reactor and by coating CNT on the coating objects located on the coating means depending on the shape of the coating objects.

### DESCRIPTION OF DRAWINGS

FIG. 1 is a process flow diagram of a general method of manufacturing a CNT coating film.

FIG. 2 is a conceptual view showing a conventional wet CNT coating film manufacturing method.

FIG. 3 is a conceptual view for explaining a configuration of an exemplary embodiment of the present invention.

FIGS. 4 and 5 are views showing examples of a structure of a coating and film supplying unit according to exemplary embodiments of the present invention.

FIG. 6 is a perspective view showing a structure of a by-product acquiring unit according to an exemplary embodiment of the present invention.

FIG. 7 is a perspective view showing a pattern coating roller structure according to an embodiment of the present invention.

FIG. 8 is a process flow diagram showing steps of a dry CNT coating film manufacturing process according to an exemplary embodiment of the present invention.

FIG. 9 shows a microphotograph of CNT manufactured according to an exemplary embodiment of the present invention.

### BEST MODE

Hereinafter, exemplary embodiments of the present invention will be described in detail with reference to the accompanying drawings.

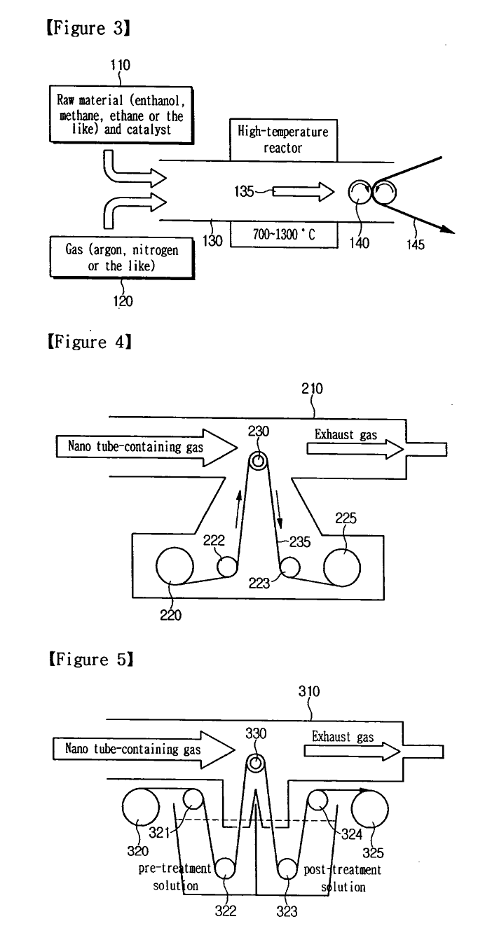

FIG. 3 is a conceptual view for explaining a configuration of an exemplary embodiment of the present invention. As shown in the FIG. 3, a structure of an exemplary embodiment of the present invention includes a high-temperature reactor 130 used for manufacture of CNT by thermal chemical vapor deposition, materials 110 and 120 provided to manufacture CNT in the high-temperature reactor 130, and a roller 140 and a film 145 as a coating and film providing unit formed in an end portion of the reactor 130.

The high-temperature reactor 130 used in the thermal chemical vapor deposition is elongated and produces a gas containing CNT. In general, the thermal vapor deposition is used to obtain a product in which CNT contained in the gas is coagulated in a bundle by cooling the end portion of the reactor. Since the coagulated bundle-like CNT will not act as nano particles, the CNT is pulverized or cut so that the CNT can be evenly dispersed into a solution.

However, the shown embodiment is a system which provides a direct application of CNT-containing gas to CNT coating, with no need to pulverize or cut CNT separately, by exposing a cold roller 140 to the CNT-containing gas and directly depositing CNT contained in the CNT-containing gas on a surface of the roller 140, instead of obtaining CNT in a bundle. That is, this embodiment is a system with no need to cool the reactor.

When CNT is produced by the thermal chemical vapor deposition, this system makes the best use of property of the CNT-containing gas obtained in the course of thermal chemical vapor deposition. The obtained CNT-containing gas 135 is generated in the reactor 130 in a high temperature state of preferably about 500 to 1500° C. (more preferably 700 to 1300° C.) at which CNT remains floated in the gas without being coagulated. At this time, when a cool surface is exposed before the gas is cooled, CNT contained in the gas is deposited on the surface with a delay and thus is not easily bundled. In addition, since CNT deposited on the cool surface is relatively tightly adhered to the surface by a van der Waals force, CNT can be directly coated on the film, and when the roller compresses the film, if adhesive strength of the roller is lower than adhesive strength of the film, CNT can be transferred onto the film.

In particular, when the produced CNT is deposited on the cool surface, since CNT is more uniformly dispersed than when CNT nano particles are dispersed in a solution, it is possible to precisely control the amount of uniformly deposited CNT with adjustment of the rotation speed of the shown roller 140. In general, it is preferable that CNT is coated at a thickness of 2 nm or above (a level that nano particles cover the film entirely), and the thickness may be increased depending on a targeted conductivity property.

In the meantime, when the direct coating process is performed using the CNT-containing gas, as shown, since a pulverizing process for even dispersion of CNT is not required, it is possible to prevent CNT from being shortened below several mm (generally 1 mm or so) due to the pulverizing process, that is, from being lowered in its conductivity and hence being deteriorated in its quality. Since the length of CNT generally obtained with the shown structure remains at 10 mm or above (several to several tens mm), the CNT coating film obtained with the shown structure has higher conductivity and better quality than a wet coating film having the same distribution and thickness because of the nature of CNT that its greater length gives its higher conductivity. This can be confirmed through FIG. 10.

In addition, since the shown structure does not require a separate dispersion process, there is no need to make a CNT dispersion which is necessarily produced in a wet coating method, and thus it is possible to prevent CNT from being deteriorated in its quality as an outer wall of CNT acts as an insulator by being surrounded by the CNT dispersion.

Accordingly, the CNT coating method of the present invention provides not only a simplified process but also dramatic improvement in quality of CNT as compared to the conventional wet coating method.

While process conditions on the generation of CNT in the thermal chemical vapor deposition with the shown structure may be combined in various ways, the raw material, the catalyst 110, an auxiliary material and the transporting gas 120 applied to the shown embodiment may be combined as follows.

First, the transporting gas may be typically an argon gas, a nitrogen gas, or other gas having low reactivity, and the raw material may be a material providing carbon which becomes a raw material of CNT, for example a methane gas, an ethylene gas, ethanol, acetylene or the like.

The catalyst may be nano particles of transition metal such as iron, cobalt, nickel or the like. However, since it may be difficult to acquire metal particles having a small size (a diameter of 1 nm or so), a raw material such as ferrocene or iron chloride may be used as the catalyst. Such a raw material is decomposed at a high temperature to become catalyst nano particles.

The auxiliary material, which serves to promote growth of CNT and increase catalyst efficiency and purity of CNT, may be a mixture of a large quantity of hydrogen and a small quantity of oxygen, water and thiophene.

At this time, the temperature of the reactor 130 preferably remains at 700 to 1300° C. and the temperature of a portion at which the roller 140 is located may be adjusted within the same temperature range. However, in a case where the temperature of the portion at which the roller 140 is located is hardly maintained to be equal to the temperature of the reactor, the temperature of the portion may be lower than the temperature of the reactor 130 (for example, 70% of the temperature of the reactor or 500° C.). However, even when the temperature of the portion is lower than the temperature of the reactor, a state where CNT is contained in the gas without being coagulated should be maintained.

Although by-products and impurities may be contained in the CNT-containing gas obtained through the above-described processes, the by-products has little effect on the coating process, and since the impurities can be reduced to 1% or below depending on adjustment of the process conditions, the above-described direct coating method produces no or little performance deterioration due to the impurities.

FIG. 4 shows details of the coating and film supplying unit shown in FIG. 3, in which units required for coating and film supplying and a film are disposed within a structure with extension of the reactor.

The shown structure has a reactor extension 210, which is an airtight space, in addition to the reactor. In the reactor extension 210 are disposed a cold roller 230 and film supplying units 220, 222, 223 and 225 for supplying and winding a film 235 via the roller 230. It is preferable that the film supplying units keeps apart from the cold roller 230 which performs CNT coating (i.e., CNT deposition) and their temperature is higher than the temperature of the cold roller 230. In the meantime, at an end portion of the reactor extension 210 may be formed an exhaust port through which a gas remaining after extraction of CNT from the CNT-containing gas can be exhausted.

In this case, since both of the roller 230 and the film supplying units 220, 222, 223 and 225 for supplying and winding the film 235 have to be located within the reactor extension 210, the size of the reactor extension may increase and thus an auxiliary heater or other means may be required to keep the reactor extension in a high-temperature state (70% of the temperature of the reactor or 500° C.).

In the meantime, in addition to the shown single reactor extension 210, a plurality of reactor extensions having different structures and sizes may be constructed. The constructed reactor extension(s) 210 can use metal and nonmetallic materials having high heat resistance. In addition, the reactor extension 210 may employ simple stainless pipes or structures, which may result in decrease of construction costs. In addition, the reactor extension may be detachably combined to the end portion of the reactor, thereby facilitating replacement of the roller and the film as necessary.

FIG. 5 shows another embodiment of the coating and film supplying unit shown in FIG. 3. As shown, a reactor extension 310 is constructed in such a manner that a cold roller 330 is directly exposed to a CNT-containing gas obtained in a reactor. Film supplying units 320, 321, 322, 323, 324 and 325 for supplying and winding a film may be located outside the reactor extension 310. In this case, in order to prevent the gas from flow out and increase efficiency of film supplying and winding, at least some of the film supplying units 320, 321 and 322 are disposed within a water tank containing a pre-treatment solution. The film passes through the pre-treatment solution and then is provided to the roller 330 within the reactor extension 310. The film coated with CNT by the roller 330 passes through a water tank containing a post-treatment solution, and then is discharged to the outside and is wound. In this case, at least some of the film winding units 323, 324 and 325 is disposed within the water tank containing the pre-treatment solution. While the coated film passes through the post-treatment solution, CNT coated on and adhered to this film is prevented from being washed away or deteriorated due to adhesion of the film or a van der Waals force.

With the above-described structure in which the water tanks containing the pre-treatment solution for film surface treatment and the post-treatment solution for washing treatment are respectively disposed in a film supplying port and a film discharging port formed in the reactor extension 310, the internal gas (CNT-containing gas) of the reactor extension 310 is prevented from being discharged to the outside while the film passes through the reactor extension 310. In this case, at an end portion of the reactor extension 310 is formed an exhaust port through which a gas remaining after deposition of CNT on the film can be exhausted.

Of course, the shown structure may be freely modified as long as the film can be supplied and discharged without the internal gas being flown out and CNT can be directly deposited and coated on the film from the CNT-containing gas while the film passes through the cold roller which is colder than the reactor. In the meantime, this structure can be applied to a case where the heat-resistant temperature of the film is lower than the internal temperature of the reactor extension 310 (70% of the temperature of the reactor or 500° C.).

In the structure having the coating and film supplying units and the reactor extension shown in FIGS. 4 and 5, instead of direct coating of CNT on the film by the temperature of the roller which becomes cold by water cooling or the like when the film contacts the roller, as shown, a roller part for coating may be configured such that CNT is deposited on one roller and then the film passing between the one roller and another adjacent roller, with the film's surface having adhesion higher than that of the another adjacent roller, is coated with CNT by compression by the rotation of the another adjacent roller. In the meantime, as an additional post-treatment process, the coating film may be additionally coated with a polymer in order to completely adhering CNT to the coating film.

By-products may be produced in the course of CNT coating and thus means for treating the by-products should be considered. In general, since the roller for CNT coating is larger than the film, CNT may remain in a portion of the roller where the roller does not contact the film. Although the remaining CNT may be an unnecessary by-product which obstructs processes, since such CNT has quality so high as to maintain relatively long length without being bundled, it may be recovered and sold as a separate product or may be used as a separate material.

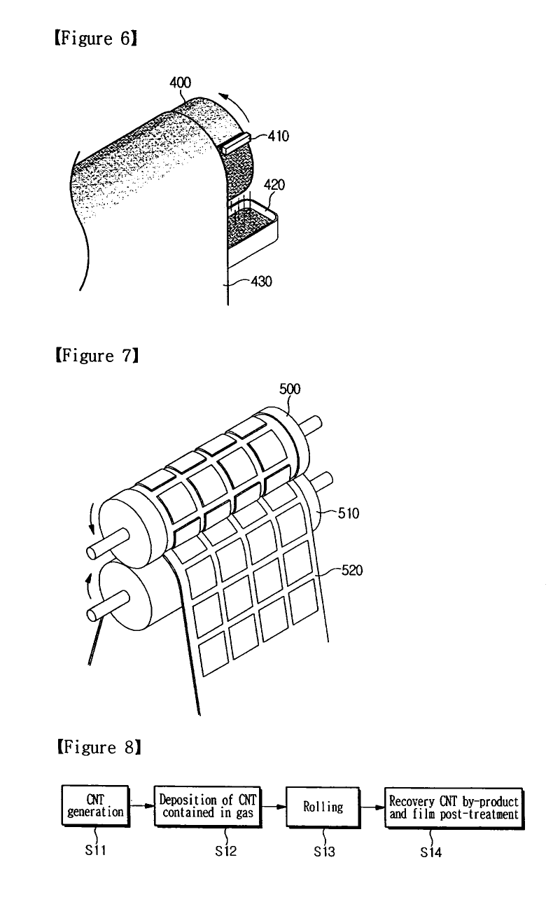

FIG. 6 shows a configuration for recovering CNT deposited on a side of a roller. As shown, CNT deposited on a side of a roller 400 where a film 430 is not present is brushed away in a mechanical manner using a brush 410 and is collected in a separate container 420.

FIG. 7 shows that CNT coating corresponding to a pattern is possible using a roller 500 on which the pattern is formed. As shown, patterned CNT may be directly coated on a film adhered to a surface of the roller 500 or a film 520 coated with patterned CNT may be printed by compression using an auxiliary roller 510.

In the meantime, with the shown pattern, since CNT formed in engraved portions is not coated on the film, unused CNT may be collected from the engraved portions and portions where the film does not pass using a brush or the like.

In addition, the shown example may be modified to peel CNT having a certain pattern from the film coated with CNT. In some cases, it is also possible to manufacture two kinds of coating films (films having a remaining pattern and a peeled pattern) at once.

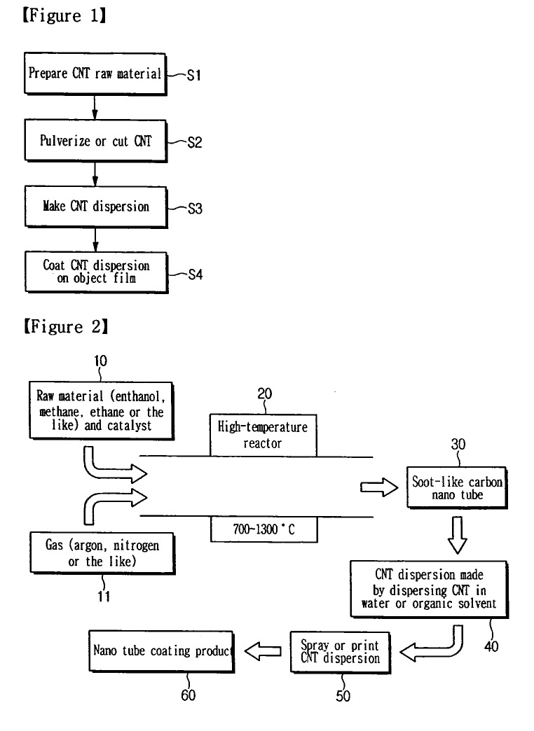

FIG. 8 shows a process of manufacturing the CNT coating film according to the above-described embodiment, which substantially corresponds to one of four processes shown in FIG. 1. That is, three of the four processes shown in FIG. 1 may be omitted.

As shown, first, a raw material, a transporting gas, an additional material and a catalyst are provided and a CNT generation reaction is induced in a high-temperature reactor (S11). As a CNT-containing gas generated according to the reaction in the high-temperature reactor flows and moves an end portion of the reactor, CNT is deposited on a cold roller itself or a film adhered to the roller with time, without being bundled (S12). While consecutively moving the film coated with the deposited CNT as the roller moves, a CNT coating film is consecutively manufactured (S13). Unnecessary CNT by-products are collected and recovered at the same time of consecutively manufacturing the CNT coating film, and as necessary, a post-treatment of washing the CNT coating film or completely fixing the CNT coating film by coating the film with a polymer is performed (S14).

That is, without changing a process site, it is possible to achieve the consecutive CNT generation, the CNT coating film manufacture and the additional CNT by-product recovery.

In addition, the obtained CNT coating film has high uniformity, as compared to a wet coating method, and hence low variation of conductivity and surface resistance. Further, since the CNT coating film has long CNT, the film increases in its conductivity and decreases in its surface resistance when CNT is coated on the film at the same thickness. That is, for example, if the CNT coating film of the present invention has the same conductivity and surface resistance as a CNT coating film manufactured by a wet coating method, it is possible to manufacture a transparent electrode or a transparent heater having very high transparency.

For example, an application of the CNT coating film to a heater requires surface resistance of 0.10 Ohm/Sq (for 12 V low voltage heater) to 10000 Ohm/Sq (for 120 V high voltage heater). Theoretically, 1 nm coating of CNT on the film gives surface resistance of 1000 Ohm/Sq. However, the conventional wet coating method requires 10 nm CNT coating in order to obtain the same surface resistance due to the above-mentioned various performance deterioration factors. However, the dry coating method of this embodiment essentially overcome the performance deterioration factors of the wet coating method, which results in significant reduction of CNT thickness required for CNT coating and hence achievement of more transparent coating. Thus, this embodiment enables reduction of required CNT thickness and hence saving of material and production time and further increase of film transparency for maximization of applicability.

While the configuration and operation of coating CNT on the film have been illustrated in the above embodiments, it is noted that the CNT coating is not limited to the film as a coating object. That is, the illustrated embodiments address a complicated consecutive CNT coating film manufacturing method, however it is to be fully understood to those skilled in the art that the present invention may be applied to intermittent coating of CNT on a more simple coating object and consecutive coating of CNT on a plate-like coating object. Thus, the dry CNT coating method may be applied to coating of CNT on various kinds of slices or pieces, cubic objects and so on without being limited to the roller and the coating of CNT on the film. This means that a coating plate having a cooling function or other cooling structures for coating may be applied in various ways to the CNT coating method, instead of the cooling roller.

For example, CNT may be coated on a glass plate placed on a cooling plate by supplying a CNT-containing gas to the glass plate. In addition, CNT may be coated on a surface of cubic cup by lowering the temperature of the cup with the cup inserted in a cooling structure having a shape corresponding to the inner surface of the cup. Further, when a means for coating CNT through cooling is added with a position adjusting function, it is possible to evenly expose a coating surface of a coating object to a CNT-containing gas supplied from a reactor.

Moreover, the dry CNT coating method of the present invention may be applied to consecutive coating objects other than the film. In this case, the supply of consecutive plates or structures may also be applied with a modification of the film supplying configuration through the roller.

That is, with the application of the dry CNT coating method of the above embodiments, it is possible to easily coat consecutive coating objects or inconsecutive single coating objects with CNT with high quality.

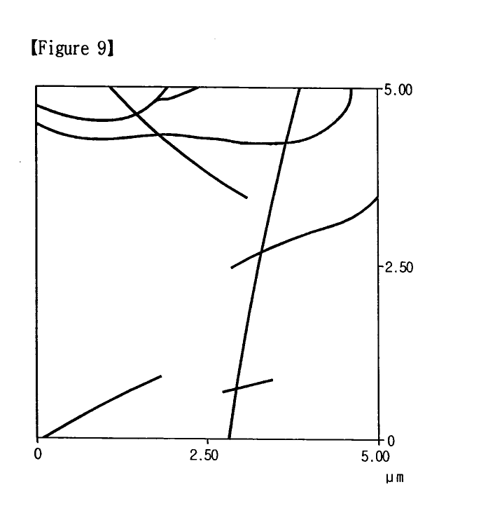

FIG. 9 shows a microphotograph of CNT directly coated from a CNT-containing gas at a very low density. It can be seen from the microphotograph that the length of CNT is elongated to exceed 5 mm which is an observation limit and CNT forms an electrical network with adjacent CNT by this length despite of sparse density. It can be easily guessed that a conventional wet coating method in which CNT is pulverized at a length of 1 mm or so and dispersed can not achieve the electrical network at the same density. Accordingly, it can be seen that the dry CNT coating method of the embodiments gives better electrical characteristics than the conventional wet coating method.

As described above, in the dry CNT coating method of the embodiments, by generating the CNT-containing gas and then performing a direct CNT coating from the CNT-containing gas, CNT can be coated on diverse coating objects in a single process. This allows dramatic saving of process time, material and costs and substantial improvement of electrical characteristics due to coating of even dispersed CNT having the length of several or several tens mm, thereby making it possible to manufacture more transparent CNT coating film suitable for various applications. On the other hand, the dry CNT coating method has no performance deterioration factor since this method does not generate dispersion by-products which may be generated in the conventional wet coating method. Accordingly, the dry CNT coating method can provide excellent characteristics in various evaluation indexes such as process, yield, limit of coating objects, costs, coating thickness, transparency, electrical conductivity, surface resistance and so on.

That is, it possible to product low-priced and high-quality CNT coating products in large quantities, which can be utilized as CNT electrodes, heaters, EMI shields and so on.

While the present invention has been particularly shown and described with reference to exemplary embodiments thereof, it will be understood by those skilled in the art that various changes in form and details may be made therein without departing from the spirit and scope of the present invention as defined by the appended claims and equivalents thereof.

1. A carbon nano tube coating apparatus comprising:
a reactor which remains at a predetermined range of high temperature for generating a carbon nano tube-containing gas; and
a coating and film supplying unit,
the coating and film supplying unit comprising:
a roller which is formed in an end portion of the reactor, remains at a temperature lower than the temperature of the reactor, and is deposited with a carbon nano tube from a high temperature carbon nano tube-containing gas which is generated in the reactor and has the temperature range of the reactor; and
a means for conveying a film through the roller.

2. The carbon nano tube coating apparatus according to claim 1, wherein the coating and film supplying unit is disposed in a space formed by extending the end portion of the reactor in an airtight manner.

3. The carbon nano tube coating apparatus according to claim 1, wherein the coating and film supplying unit is configured to convey the film to the roller so that the carbon nano tube is directly deposited on the film or is configured to transfer and coat the carbon nano tube deposited on the roller on the film using a separate compressing roller.

4. The carbon nano tube coating apparatus according to claim 1, wherein the roller has an embossed pattern to be coated on the film.

5. The carbon nano tube coating apparatus according to claim 1, wherein the roller includes a means for recovering a carbon nano tube deposited on a portion of the roller where the roller does not contact the film.

6. The carbon nano tube coating apparatus according to claim 1, wherein the roller includes an axis through which a liquid refrigerant passes.

7. The carbon nano tube coating apparatus according to claim 1, further comprising a means for washing the coated film obtained through the coating and film supplying unit or coating the coated film obtained through the coating and film supplying unit with a polymer.

8. A carbon nano tube coating apparatus comprising:
a carbon nano tube generating unit for generating a carbon nano tube-containing gas in a reactor having a predetermined range of temperature based on a transporting gas, a raw material, a catalyst and an auxiliary material;
a roller unit including a cooling means disposed in an end portion of the reactor for directly depositing a carbon nano tube from the carbon nano tube-containing gas remaining at the temperature of the reactor;
a film supplying unit for supplying a film to the roller unit and winding the film passing through the roller unit; and
a reactor extension extended from the reactor such that at least the roller unit is exposed to the inner side of the reactor, a gas discharging port being formed in a portion of the reactor extension.

9. A carbon nano tube coating method comprising the steps of:
providing a transporting gas, a raw material, a catalyst and an auxiliary material to a reactor and generating a carbon nano tube-containing gas in a thermal chemical vapor deposition manner; and
while the generated carbon nano tube-containing gas of the temperature of the reactor passes a roller, which is located in an end portion of the reactor and has a temperature lower than the temperature of the reactor, through the reactor, directly coating a carbon nano tube contained in the carbon nano tube-containing gas on a film passing through the roller.

10. The carbon nano tube coating method according to claim 9, wherein the coating step comprises the step of depositing the carbon nano tube contained in the carbon nano tube-containing gas on the roller and compressively coating the carbon nano tube deposited on the roller on the film passing between the roller and an auxiliary roller disposed adjacent to the roller.

11. The carbon nano tube coating method according to claim 9, wherein the coating step comprises the step of depositing the carbon nano tube contained in the carbon nano tube-containing gas on a surface of the film passing through the roller.

12. The carbon nano tube coating method according to claim 9, wherein the coating step comprises the step of recovering a carbon nano tube deposited on a non-coated region of the roller through a recovery means.

13. The carbon nano tube coating method according to claim 9, wherein the coating step comprises the step of depositing the carbon nano tube in the carbon nano tube-containing gas according to a pattern formed on the roller and compressively coating the deposited carbon nano tube on the film passing between the roller and an auxiliary roller disposed adjacent to the roller according to the pattern formed on the roller.

14. The carbon nano tube coating method according to claim 9, further comprising: after the coating step, a post-processing step of washing the coated film or coating and fixing the coated film with a polymer.

15. A carbon nano tube coating apparatus comprising:
a reactor for thermal chemical vapor deposition of a carbon nano tube;
a reactor extension extending from an end portion of the reactor for forming a coating space to which a carbon nano tube-containing gas generated in the reactor is supplied; and
a coating means located within the reactor extension for keeping an object to be coated with the carbon nano tube contained in the carbon nano tube-containing gas at a temperature lower than the temperature of the reactor and the temperature of the carbon nano tube-containing gas.

16. The carbon nano tube coating apparatus according to claim 15, wherein the coating means comprises a position varying means for varying a position of the object to be coated such that a coating region of the coating object is evenly exposed to the carbon nano tube-containing gas provided through the reactor while lowering the temperature of the coating object.

17. The carbon nano tube coating apparatus according to claim 15, wherein the coating means comprises a cooling means for lowering the temperature of the object to be coated and a supplying means for consecutively supplying the object to be coated to the cooling means.

18. The carbon nano tube coating apparatus according to claim 15, wherein the object to be coated is at least one of an intermittent object including a plate-like slice and a cubic object with unevenness and a consecutive object including a film and a plate-like object which can be consecutively supplied.
